(19) United States
(12) Patent Application Publication
(10) Pub. No.: US 2012/0081111 A1
(43) Pub. Date: Apr. 5, 2012

(54) System For Signal Detection of Specimen Using Magnetic Resistance Sensor and Detecting Method of The Same

(75) Inventors: Jeong Ryul Kim, Seoul (KR); Chung Wan Lee, Seoul (KR); Man Hue Choi, Seoul (KR); Ji Hye Yang, Seoul (KR); Mun Suk Kang, Seoul (KR); Young Muk Kim, Seoul (KR)

(73) Assignee: LG Innotek Co.,Ltd, Seoul (KR)

(21) Appl. No.: 13/257,161

(22) PCT Filed: Mar. 17, 2010
(86) PCT No.: PCT/KR2010/001639

§ 371 Date: Nov. 28, 2011

(30) Foreign Application Priority Data
Mar. 17, 2009 (KR) 1020090022778

(51) Int. Cl. G01R 33/09

(52) U.S. Cl. 324/252

(57) ABSTRACT

The present invention is to provide a measurement system using a magneto-resistance sensor, comprising a magneto-resistance sensor configured to sense a magnetic component of a target combined with a magnetic particles and an external magnetic field supplying unit configured to provide an external magnetic field of a first and a second directions to the magneto-resistance sensor, wherein the external magnetic field supplying unit comprises a magnetic field compensating unit configured to compensate a loss of magnetic field by circulating the external magnetic field of the second direction.

### TECHNICAL FIELD

The present invention relates to a signal detection system for quantitatively measuring characteristics of magnetic particles by using a magneto-resistive sensor and a detecting method.

### BACKGROUND ART

Generally, a magneto-resistive sensor is a sensor configured to measure magnitude (strength) and direction of a magnetic field or a magnetic line of force, and, for example, to measure the magnetic field by using characteristic variation of a material according to effect of the magnetic field. Based on a quantum Hall effect and a magnetoresistive effect, a hall device and a magnetoresistive device as well as a video tape recorder (VTR), a tape recorder, and etc. are fabricated. Herein, the material having a characteristic changed in response to a magnetic field is used for applying a magnetic field to a target (e.g., specimen) connected to a magnetic particle and measuring variation of magnetic field.

The magnetic particle made from a magnetite is a kind of promising tag configured to detect existence of a target of which surface is coated by a biomaterial, and particularly studied for long time in a biochemistry field. However, since a magnetic signal generated from a magnetic particle having very small volume is too weak, it is still remained as a difficult but challengeable issue to fabricate a magnetic detector. Until now, the magnetic detector is studied in various ways.

Regarding of the magnetic detector, there are superconducting quantum interference devices (SQUID); but the SQUID is not applicable to a real world because the SQUID has a complexity and very low temperature elements. Another conventional method is suggested by Rohr. Referring to Rohr's U.S. Pat. Nos. 5,445,970 and 5,445,971, there are some force magnetometric methods, but Rohr's method has a limitation to quantitative and high sensitive measurement.

Method and apparatus for making quantitative measurements of localized accumulations of target particles having magnetic particles bound thereto are published by Simmonds. In Simmonds' U.S. Pat. No. 6,046,585, a hall sensor is used. Further, in U.S. Patent No. 6,437,563, a giant magneto-resistance (GMR) sensor can be used. Herein, the hall sensor is a kind of conventional device to measure a magnetic field by using the Hall effect, i.e., the production of a voltage difference (the Hall voltage) across an electrical conductor, transverse to an electric current in the conductor and a magnetic field perpendicular to the current. The GMR sensor including a thin film having a resistance changed if an external magnetic field is applied is a device using a spin-aligned magnetic layer, e.g., spin-up or spin-down electron in the magnetic layer. Recently, the GMR sensor is studied for developing a biosensor. In view of sensitivity, the GMR sensor is better than the hall sensor, but until now, the GMR sensor is not used in real world for high sensitive detection because of various reasons.

Referring to U.S. Pat. No. 6,437,563, Simmonds suggests the GMR sensor is applicable to a high sensitive detection system. However, because a system generates a magnetic field of 500 to 1000 Gauss at a high frequency (100 KHz) by using a AC drive field in order to magnetize magnetic materials, a lot of power is consumed. For overcoming above problem, Sager suggests a method using a DC magnetic field, instead of the AC drive field, through a permanent magnet in U.S. Pat. No. 6,518,747. As a method for making quantitative measurements of localized accumulations of target particles, a hall sensor and a giant magneto-resistance (GRM) sensor are suggested, but may not be put to practical use because of inaccuracy of sensitivity and complex design of measuring device.

### DISCLOSURE OF INVENTION

### Technical Problem

An embodiment of the present invention is to provide a system for measurements of target particles using a magneto-resistance sensor, and a measurement system for maximizing sensitivity of the magneto-resistance sensor by supplying a magnetic field in directions of Y and Z axes of the magneto-resistance sensor. Further, to maximize sensitivity, the system includes a magnetic compensating unit for forming a magnetic field of Z-axis direction by circulating the magnetic field being loss to keep strength of magnetic field and efficiency of high sensitivity.

### Solution to Problem

In an embodiment of the present invention, a measurement system using a magneto-resistance sensor comprises a magneto-resistance sensor configured to sense a magnetic component of a target combined with a magnetic particles and an external magnetic field supplying unit configured to provide an external magnetic field of a first and a second directions to the magneto-resistance sensor, wherein the external magnetic field supplying unit comprises a magnetic field compensating unit configured to compensate a loss of magnetic field by circulating the external magnetic field of the second direction.

Particularly, the magnetic field compensating unit comprises a magnetic field circulating module configured to circulate an outflow portion of the external magnetic field and a magnetic field generating unit included inside the magnetic field circulating module. Herein, the magnetic field circulating module may comprise magnetic field generating units arranged in opposite sides in an interior space and a closed structure for circulating a magnetic field at an outer space.

The external magnetic field supplying unit may comprise a first supply unit configured to provide a magnetic field of horizontal direction (Y-axis) to the magneto-resistance sensor and a second supply unit configured to provide a magnetic field of vertical direction (Z-axis) to the magneto-resistance sensor. The first and second supply units may be formed in one chip to reduce manufacturing cost and increase space efficiency.

The magnetic field generating units of the first and second supply units may include one or more of a solenoid coil, a Helmholtz coil, an electromagnet yoke, and a permanent magnet. The magneto-resistance sensor may include a giant magneto-resistance (GMR) sensor.

A magnetic field generated by the first supply unit may be formed in response to a DC current. A range of magnetic field of the first supply unit or a response available range (sensitivity) of the magneto-resistance sensor is 200 to 300 Gauss. Particularly, a range of magnetic field of the second supply unit is 1000 to 4500 Gauss.

Herein, the magnetic field can be different according to a kind of magneto-resistance sensor. For example, the magnetic field of 200 to 300 Gauss is applied in a linear range, i.e., sensitivity, of magneto-resistance sensor.

In the measurement system, a target locking unit configured to fix the target may be included, wherein the target locking unit includes a measurement cartridge or a membrane. The target may comprise a biomaterial including antigens.

In the measurement system, the magnetic component may be sensed contactless a measurement cartridge or a membrane. The measurement system may further comprise a scanner configured to scan the magnetic component sensed by the magneto-resistance sensor. Herein, the scanner may comprise a target supporting unit configured to support the target and a loader configured to load the target locking unit fixing the target.

Further, the measurement system may comprise a measurement processing unit configured to extract and analyze electronic component from a magnetic signal sensed by the magneto-resistance sensor to output an analysis result.

In the present invention, the magnetic particles have a magnetizing force of 10 to 100 emu/g. The magnetic particles have a characteristic of super paramagnetism or paramagnetism.

In an embodiment of the present invention, it is possible to perform a quantitative measurement to a target by applying an external magnetic field to a magnetic particles and using a magneto-resistance sensor. A method for perform a quantitative measurement comprises providing a DC magmatic field for magnetizing the magnetic particles in a vertical direction (Z-axis) to the magneto-resistance sensor, providing an induced magnetic field in a horizontal direction (Y-axis) to the magneto-resistance sensor into the target to perform a measurement, choosing a value corresponding to point of minimizing a hysteresis range on a characteristic curve of the magneto-resistance sensor as a horizontal value, choosing a maximized value in a range of fixed characteristic of the magneto-resistance sensor as a vertical value, and determining an optimized point of the horizontal and vertical values as a measurement.

### ADVANTAGEOUS EFFECTS OF INVENTION

According to the present invention, a system for measuring target particles using a magneto-resistance sensor is provided, wherein a measurement system may maximizes sensitivity of the magneto-resistance sensor by supplying a magnetic field in directions of Y and Z axes of the magneto-resistance sensor. Further, to maximize sensitivity, the measurement system includes a magnetic compensating unit for forming a magnetic field of Z-axis direction by circulating the magnetic field being loss to keep strength of magnetic field and efficiency of high sensitivity.

In details, to maximize sensitivity of the magneto-resistance sensor, the measurement system applies both a DC magnetic field is applied to a side flow membrane in a Z-axis direction to achieve saturation magnetization of magnetic particles having a characteristic of super paramagnetism and the magnetic field of Y-axis direction in order to maximize sensitivity of the sensor.

According to the present invention, the measurement system mounts the target to the target locking unit, applies an external magnetic field in two directions to the magneto-resistance sensor by using the external magnetic field supplying unit, and senses a magnetic signal of the target connected to magnetic particles by using the magneto-resistance sensor to extract and analysis an electric component.

An external magnetic field is provided by using two supply units including one or more of a solenoid coil, a Helmholtz coil, an electromagnet yoke, a permanent magnet, and etc.; and at this time, magnetization of the magnetic particles is maximized and effects to the magneto-resistance sensor is minimized so that efficiency of sensitivity is maximized.

The present invention can couple a giant magneto resistance cartridge as a cartridge for biomaterial measurement to a measurement processing unit so that an electro component can be extracted and analyzed after the target combined with magnetic particles are detected and sensed. Further, if a GMR device fabricated by a conventional art is applied as a bio sensor, sensitivity to small target can be increased by contactless way between a sensing element and the target so that quantitative analysis can be smoothly performed.

Furthermore, the present invention allows Bio-diagnostics by using a contactless GMR sensor to sense a target or a specimen. If a membrane used in point of care testing (POCT) is installed to a measurement kit, more effective measurement system for the membrane can be developed.

In addition, the present invention may overcome a sensing range restricted by a size of sensing element and perform a quantitative analysis for measurement because a noise among frequencies can be classified by a dynamic scanning method.

### BRIEF DESCRIPTION OF DRAWINGS

FIG. 1 is a conceptual diagram showing an operation of a magneto-resistance sensor used in the present invention.

FIG. 2 is a block diagram describing a measurement system according to an embodiment of the present invention.

FIG. 3 is a diagram depicting a method for applying a magnetic field to a conventional hall sensor.

FIGS. 4 and 6 are diagrams showing a method for applying a magnetic field to a magneto-resistance sensor according to an embodiment of the present invention.

FIGS. 7 and 8 are diagrams showing a measurement system including an external magnetic field supplying unit according to an embodiment of the present invention.

FIGS. 9 and 10 are graphs describing variation of magnetic field by first and second supplying units according to an embodiment of the present invention.

FIG. 11 is a conceptual diagram depicting formation of horizontal and vertical magnetic field and consolidation of magnetic force.

FIGS. 12 and 13 are table and graph showing variations of current amounts and magnetic force flowing through a Helmholtz coil as an embodiment of the first supplying unit according to the present invention.

FIG. 14 is a characteristic curve for finding an optimized point of horizontal and vertical magnetic force.

FIG. 15 is a diagram showing a measurement system including an additional element for increasing efficiency of sensitivity according to an embodiment of the present invention.

FIG. 16 is a diagram describing a measurement system according to an embodiment of the present invention.

FIG. 17 shows measurement results on an experiment using a measurement system according to an embodiment of the present invention.

### BEST MODE FOR CARRYING OUT THE INVENTION

Hereinafter reference will now be made in detail to various embodiments of the present invention, examples of which are illustrated in the accompanying drawings and described below.

The present invention provides an apparatus and method for making quantitative measurements of localized accumulations of target particles in a test device, which can allow side flow of a fluid such as Micro Fluidics Chip, Glass, Plastic, Membrane, and etc., by using a giant magneto-resistance (GRM) sensor. The present invention describes problems on sensitivity performance of a conventional measurement system and suggests a method for improving the problems, and provides an apparatus and method for high sensitivity using a hall sensor as well as a magneto-resistance sensor (for example, GMR, TMR, and so on). Particularly, the present invention comprises the magneto-resistance sensor providing an external magnetic field, and a magnetic field compensating unit compensating loss of the magnetic field to form a strong magnetic field and maximize sensitivity.

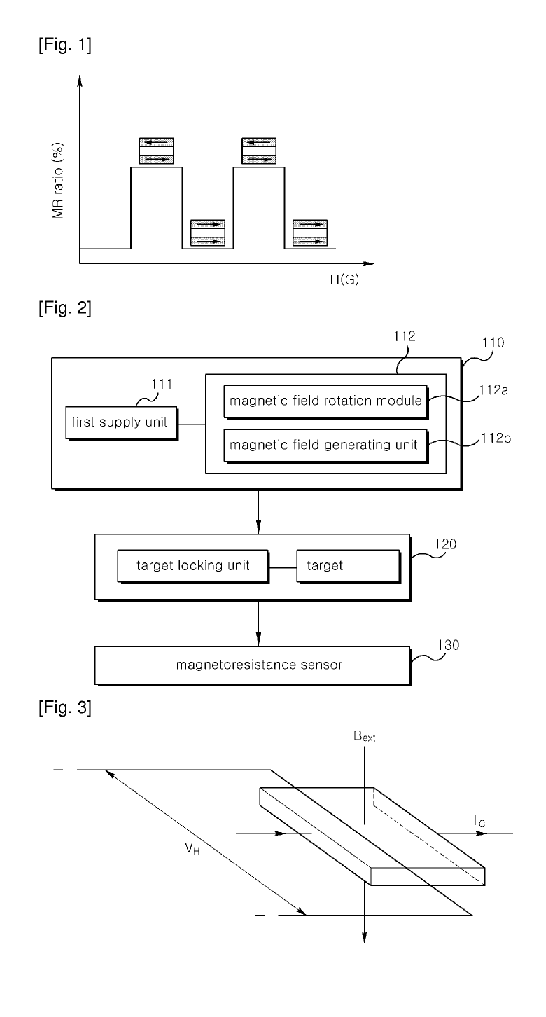

FIG. 1 is a conceptual diagram showing an operation of a magneto-resistance sensor used in the present invention. For convenience of explanation, here is a sensing principle using a giant magneto-resistance (GMR) among magneto-resistance sensors described.

FIG. 1 describes operation of a spin-value type GMR device. As shown, the GMR device includes a first ferromagnetic layer having a fixed polarity, a second ferro-magnetic layer having a changeable polarity, and a non-magnetic metal layer. If polarities of the first and second ferromagnetic layers are same, i.e., parallel, to each other, electrons spin-aligned in only particular direction can pass through conductive materials. That is, according to polarities of the first and second ferromagnetic layers, there is difference of electro resistance or electrical potential in the device. The difference of electro resistance or electrical potential can be converted into a digital signal. When an intervening layer between the first and second ferromagnetic layers is made of a metal, the device is called as GMR device.

FIG. 2 is a block diagram describing a measurement system according to an embodiment of the present invention.

As shown, the measurement system includes a target for measurement, a target locking unit 120 configured to locking up the target, an external magnetic field supplying unit 110, and a magneto-resistance sensor 130. The measurement system mounts the target to the target locking unit 120, applying an external magnetic field by using the external magnetic field supplying unit 110, and sensing a magnetic signal of the target connected to magnetic particles by using the magneto-resistance sensor 130 to extract and analysis an electric component. Herein, the magnetic particles may have a magnetization of 10 to 100 emu/g. At this case, the magnetic particles have a characteristic of super paramagnetism or paramagnetism.

The external magnetic field supplying unit 110 may provide a magnetic force having first and second directions of the magneto-resistance sensor 130. The magnetic force having first and second direction includes a magnetic force (Y-axis) horizontal to the magneto-resistance sensor 130 generated by a first supply unit 111 and another magnetic force (Z-axis) vertical to magneto-resistance sensor 130 occurred by a second supply unit 112. Herein, a horizontal direction and a vertical direction means a direction of strictly horizontal and vertical to inputted faade of the magneto-resistance sensor 130 as well as a direction of generally horizontal and vertical thereto, having a predetermined range.

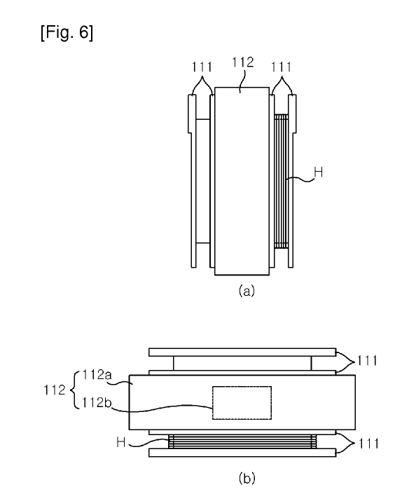

The second supply unit 112 providing a magnetic force in a vertical direction (Z-axis) of the magneto-resistance sensor 130 further includes a magnetic field compensating unit configured to compensate loss of magnetic field by circulating an external magnetic force having the second direction. The magnetic field compensating unit includes a magnetic field circulating module 112a configured to circulating an external magnetic force being loss and a magnetic field generating unit 112b included in the magnetic field circulating module 112a. The magnetic field generating unit 112b provides a magnetic force of Z-axis direction, and provided magnetic force which might be spilled into an external area is circulated, i.e., prevented from spilling, by the magnetic field circulating module 112a so that a strong magnetic field is maintained and measurement sensitivity can be increased. More detailed description about these operations is later, referring to FIG. 6.

According to embodiments of the present invention, the magneto-resistance sensor 130 includes one of an ordinary magneto-resistance (OMR) sensor, an anisotropic magneto-resistance (AMR) sensor, a giant magneto-resistance (GMR) sensor, a colossal magneto-resistance (CMR) sensor, a tunneling magneto-resistance (TMR) sensor, a magnetic tunneling junction (MJT) sensor, a planar Hall resistance sensor. Preferably, the giant magneto-resistance (GMR) sensor can be used as the magneto-resistance sensor 130.

Referring to FIGS. 3 to 5, the measurement system comprising a GMR sensor according to an embodiment of the present invention is described in details.

FIG. 3 depicts a method for applying a magnetic field to a conventional hall sensor. In the conventional art, for achieving saturation magnetization of magnetic particles having a characteristic of super paramagnetism, a DC magnetic field is applied in a vertical direction Bₑₓₜ to a Hall sensor by a permanent magnet. Using an AC bias current applied in a direction I_{c} vertical to the magnetic field, a Hall sensor operates based on an excited electron and a biased electron. The symbol V_{H} is an electromotive force occurred when a current is applied vertical to the magnetic field. Accordingly, in the conventional art, the Hall sensor operates in only vertical direction to currents applied thereto, and sensitivity of the Hall sensor is decreased.

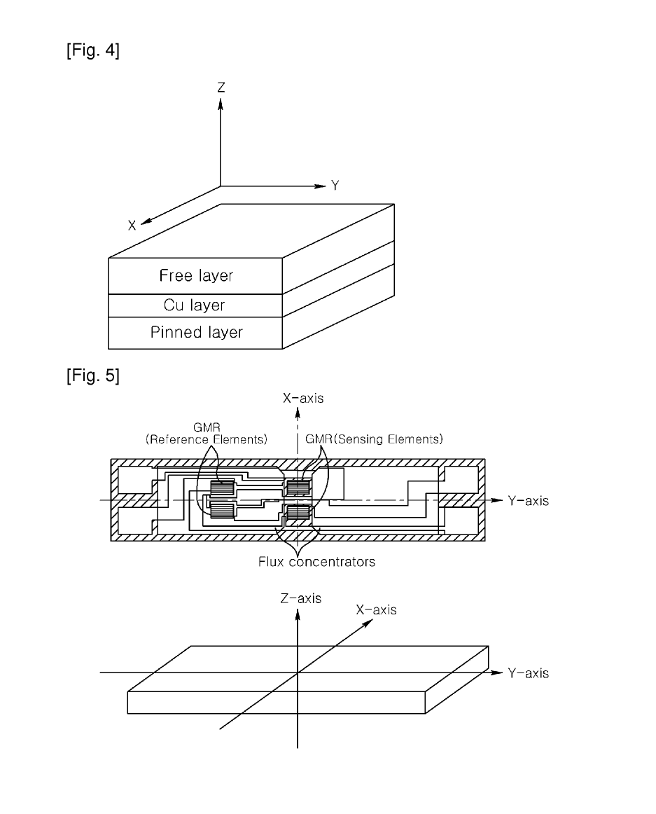

FIGS. 4 and 5 are diagrams showing a GMR sensor according to an embodiment of the present invention. The measurement system includes the GMR sensor. Arrows shown in figures are a horizontal direction (X-axis) to a ferromagnetic film, another horizontal direction (Y-axis) to the ferromagnetic film, and a vertical direction (Z-axis) to the ferromagnetic film, wherein the ferromagnetic film is included in the GMR sensor. In this case, the GMR sensor is affected strongly by a magnetic field of Y-axis direction, but lesser by a magnetic field of X-axis direction. Also, the GMR sensor has no effect in response to a magnetic field of Z-axis direction. According to the magnetic field of Y-axis direction, the GMR sensor can control a bias in a linear range.

To maximize a sensitivity of the GMR sensor, the measurement system applies a DC magnetic field in a Z-axis direction to achieve saturation magnetization of magnetic particles having a characteristic of super paramagnetism, and applies a magnetic field of a Y-axis direction to control a bias. Herein, it is very effective in view of signal-to-noise ratio that an induced magnetic field occurred due to a DC current is used as the magnetic field of a Y-axis direction. Preferably, localized accumulation of magnetic particles in a side flow membrane is transferred by a scanning of direction same to the induced magnetic field of Y-axis direction.

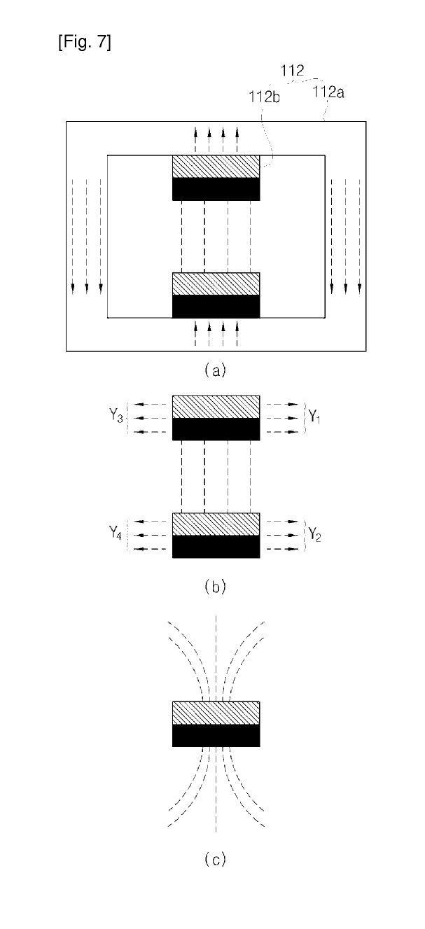

FIGS. 6 and 7 are diagrams showing a measurement system including an external magnetic field supplying unit according to an embodiment of the present invention. FIG. 6(a) is a side view, and FIG. 6(b) is a top view.

The external magnetic field supplying unit includes a first supply unit 111 configured to provide a magnetic field of Y-axis direction to the magneto-resistance sensor, a second supply unit 112 configured to provide a magnetic field of Z-axis direction to the magneto-resistance sensor, a measurement target, such as a membranes, located inside the second supply unit 112, and a scanner (not shown).

The second supply unit 112 providing a magnetic force in a vertical direction (Z-axis) of the magneto-resistance sensor 130 further includes a magnetic field compensating unit configured to compensate loss of magnetic field by circulating an external magnetic force having the second direction.

The magnetic field compensating unit includes a magnetic field circulating module 112a configured to circulating an external magnetic force being loss and a magnetic field generating unit 112b included in the magnetic field circulating module 112a. The magnetic field generating unit 112b provides a magnetic force of Z-axis direction, and provided magnetic force which might be spilled into an external area is circulated, i.e., prevented from spilling, by the magnetic field circulating module 112a so that a strong magnetic field is maintained and measurement sensitivity can be increased. Referring to FIG. 7, the magnetic field generating unit 112b according to an embodiment of the present invention includes two permanent magnets separated at upper area and lower area inside the magnetic field circulating module 112a. Structure of the magnetic field generating unit 112b in FIG. 7 is depicted in details, referring to side and top views. As shown in FIG. 7, the magnetic field generating unit 112b is formed to have a space separating two magnets, each being opposite to each other.

The magnetic field generating unit 112b generating a magnetic field in the first supply unit 111 and the second supply unit includes a solenoid coil, a Helmholtz coil, an electromagnet yoke, a permanent magnet, and so on. That is, the magnetic field generating unit 112b includes one or more of a solenoid coil, a Helmholtz coil, an electromagnet yoke, a permanent magnet, and etc., and the first and second supply units can includes the same or different components.

As described above, in the measurement system, the DC magnetic field is applied to a side flow membrane in a Z-axis direction to achieve saturation magnetization of magnetic particles having a characteristic of super paramagnetism, and the magnetic field of Y-axis direction is applied to control bias in order to maximize sensitivity of the sensor. That is, measurement target 112 is transferred in Y-axis direction so that sensitivity of the sensor is increased by scanning in Y-axis direction. In an embodiment of the present invention, a magnetic field applied to the first supply unit has a range of 200 to 300 Gauss, and a response range of the GMR sensor is from 200 to 300 Gauss. Further, a magnetic field applied to the second supply unit has a range of 1200 to 1400 Gauss.

Hereinafter, in an embodiment of the external magnetic field supplying unit, the first supply unit 111 includes a Helmholtz coil H and the second supply unit includes a permanent magnet. In another embodiment, as above described, a magnetic field supply unit can includes one or more of all devices having an applied magnetic field changed by current amounts such as a solenoid coil, a Helmholtz coil, an electromagnet yoke, a permanent magnet, and etc.

In an embodiment, a Helmholtz coil H included in the first supply unit 111 has a size of 50×100×80 mm to adapt or embed into a small device. The Helmholtz coil includes a copper wire having a diameter of 0.5 F and coiled up 162-times. When currents of 1 A or 0.5 A are supplied, a magnetic field of 30 Gauss is occurred at a core, a central region of 5×5×5 mm, and uniformity of the magnetic field is less than 1%. The magnetic field occurred from the Helmholtz coil includes a magnetic force of Y-axis direction affecting initial-set value and operation reliability of the GMR sensor. Herein, strength of the magnetic field can be changed by a size of Helmholtz coil and amounts of current flowing into the Helmholtz coil. In the present invention, the Helmholtz coil generates a magnetic field of 30 Gauss with uniformity of less than 1% in a central region of 5×5×5 mm.

In the magnetic field generating unit 112b, two permanent magnets, each being opposite to each other, are arranged. The magnetic field circulating module 112a has a yoke structure made from pure iron (S10C), and the two permanent magnets are attached inside the yoke structure. Herein the permanent magnets include an Nd metal having a size of 20×20×10 mm. Distance between two permanent magnets is 4 cm. At surface of the permanent magnet, magnetic force is 4000 to 5000 Gauss; and at a center region between two permanent magnets, magnetic force is 1200 to 1400 Gauss.

FIG. 7 describes structure of the external magnetic field supplying unit shown in FIG. 6. In the present invention, the first supply unit includes the Helmholtz coil to provide a magnetic field of horizontal direction. To form a magnetic field of vertical direction (Z-axis), the magnetic field generating unit 112b and the magnetic field circulating module 112a are included. Referring to (a), the magnetic field generating unit 112b includes a permanent magnet. The magnetic field generating unit 112b is located inside the magnetic field circulating module 112a having a yoke structure of exposing an internal space and being sealed from external area. In this case, two magnetic field generating units 112b are arranged at opposite sides so that a magnetic field is occurred between the two magnetic field generating units 112b.

Referring to (b), magnetic field between two permanent magnets located in opposite sides are objectified as a magnetic force of straight line X and plural magnetic forces Y₁ to Y₄ moving to an external area. Thus, only two permanent magnets can make a magnetic force of straight line X, but other magnetic forces are out of range. Accordingly, the magnetic field can be easily affected by an external circumstance, and it is very difficult to obtain a stable magnetic force. If only one permanent magnet is used as shown in (c), more than magnetic forces are getting out of the range and a stable magnetic force cannot be obtained.

Referring to (a) of FIG. 6 and (a) of FIG. 7, the magnetic field circulating module 112a is included in the external magnetic field supplying unit. The magnetic field circulating module 112a blocks magnetic forces getting out of the range, which becomes loss. The blocked magnetic forces Y₁ to Y₄ move along with the magnetic field circulating module 112a so that the magnetic field around the permanent magnets becomes stable. That is, to block a magnetic force becoming loss by using the magnetic field circulating module 112a can strengthen a magnetic field of the external magnetic field supplying unit.

FIG. 8 shows uniformity of magnetic field occurred by the magnetic field circulating module 112a and the magnetic field generating unit 112b. When the magnetic field circulating module 112a having a yoke structure is included, the maximum of magnetic moment is about 1750 Gauss and uniformity of magnetic field is about 2.1%. The result is better than a case that uniformity of magnetic field is about 4.6% when the magnetic field circulating module 112a is not included. Herein, case is an embodiment of the present invention, case is that only two permanent magnets except for the magnetic field circulating module 112a are included, and case is that only one permanent magnet is included.

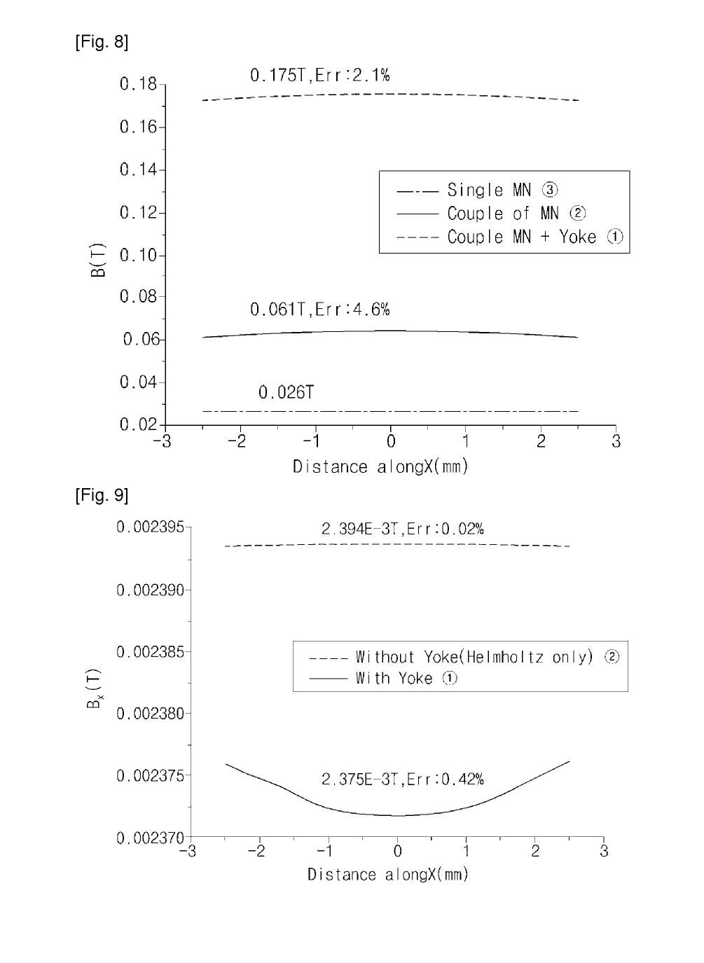

Referring to FIG. 9, magnetic field of horizontal direction (Y-axis) and vertical direction (Z-axis) is measured when an embodiment of present invention includes a first supply unit including a Helmholtz coil and a second supply unit including a magnetic field circulating module 112a and a magnetic field generating unit 112b. When the present invention includes the Helmholtz coil providing a stable magnetic force of horizontal direction and the magnetic field circulating module 112a and the magnetic field generating unit 112b providing a magnetic force of vertical direction, variation of magnetic field of horizontal direction (Y-axis) is about 0.2 Gauss and uniformity of magnetic field is less than 1%. Thus, even though a magnet having a yoke structure is used inside the Helmholtz coil, there is no adverse effect of the present invention.

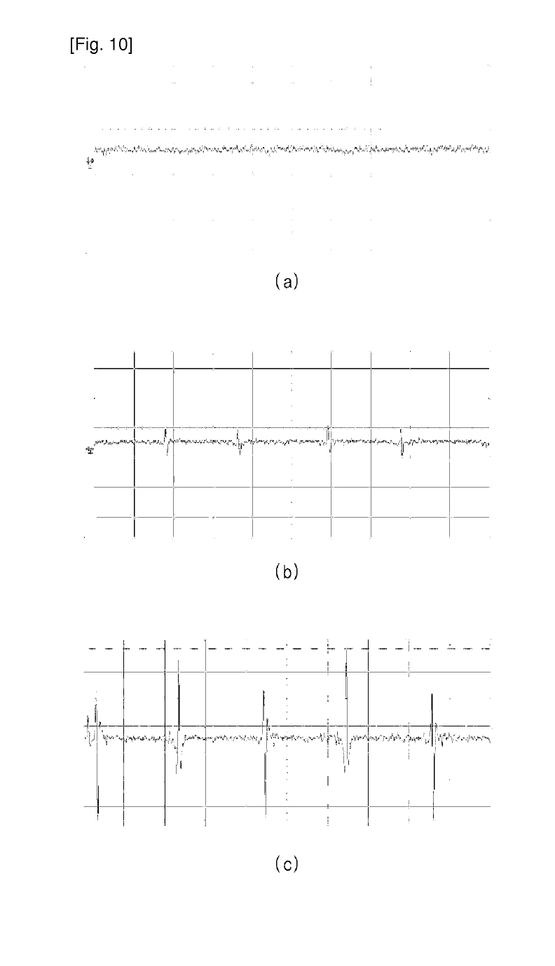

Referring to FIG. 10, characteristics of magnetic band (magnetic particles) are measured by using an external magnetic field supplying unit including a magnetic field compensating unit. Case (a) is that measurement is 130 mV if a magnetic field of horizontal direction (Y-axis) is only occurred; case (b) is that the measurement is 520 mV when a magnetic field of vertical direction (Z-axis) is only occurred; and case (c) is that measurement is 4340 mV if a magnetic field of horizontal and vertical directions. This result says that sensitivity of the sensor when the magnetic field of horizontal and vertical directions is applied is increased more 30 times than that when only magnetic field of horizontal direction (Y-axis) is applied and more 8 times than when only magnetic field of vertical direction (Z-axis) is only applied. In above experiment, conditions are as follows: the magnetic field of horizontal direction (Y-axis) is 30 Gauss, and the magnetic field of vertical direction (Z-axis) is 1250 Gauss, both measured at the center point between two permanent magnets. This phenomenon can be explained by following reasons.

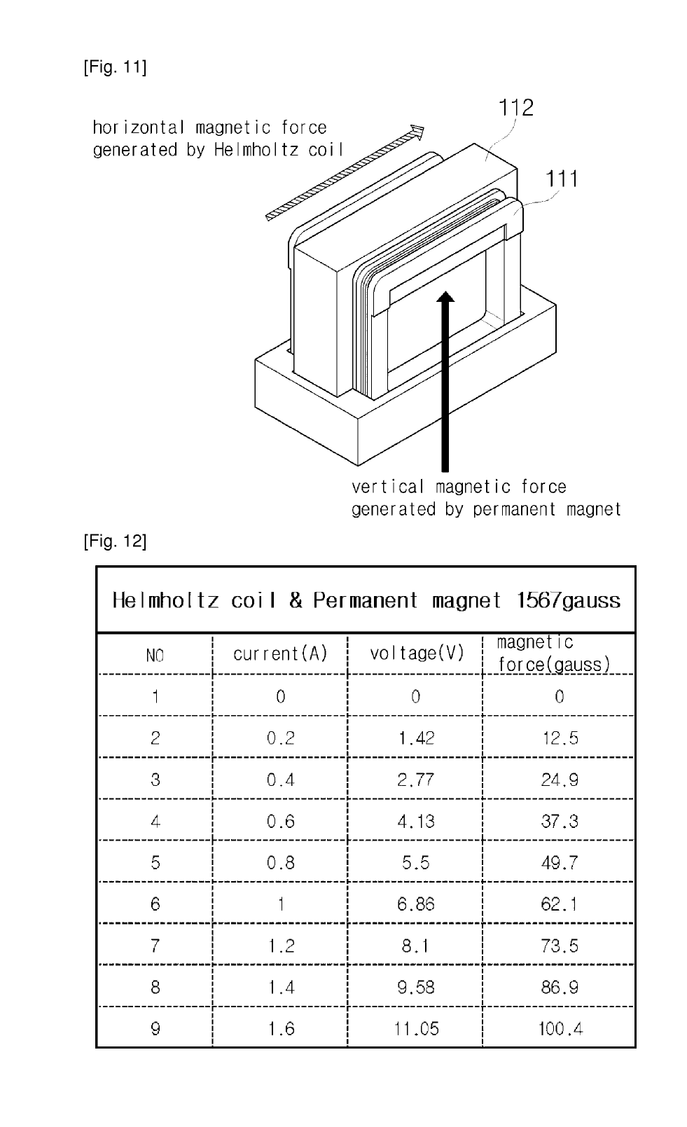

As shown in FIG. 11, the magnetic field of horizontal and vertical directions occurred by the first supply unit 111 including the Helmholtz coil and the magnetic field compensating unit including the permanent magnets forms a magnetic moment of the magnetic band (magnetic particles) as a target for measurement.

The magneto-resistance sensor can recognize a stray field of the magnetic band according to a magnetic force of vertical direction generated by the permanent magnets. At this time, as the magnetic force of vertical direction is stronger, variation of magnetic field spread outward becomes larger so that sensitivity of the sensor can be increased.

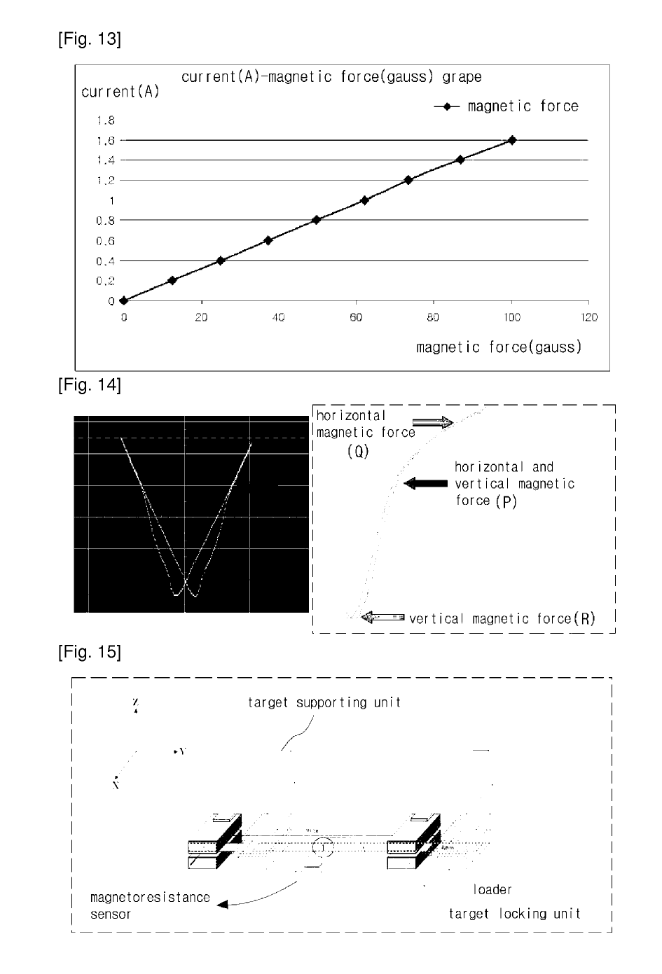

FIG. 12 describes a result of measuring a magnetic field by changing current amounts flowing through the Helmholtz coil included in the first supply unit of the external magnetic field supplying unit, shown in FIG. 6, according to an embodiment of the present invention. FIG. 13 is graph showing a magnetic force in response to variation of current amounts. As above described, a relationship between the magnetic force and the current amounts is proportional. Particularly, referring to FIG. 4e, the magnetic force can be optimized by adding a magnetic field of vertical direction.

Referring to FIG. 14, hereinafter is how to understand an optimized point of the magnetic field by combining horizontal and vertical magnetic force described, and a method for measuring a magnetic target by using the optimized point is depicted. FIG. 6 shows results of measuring variation of magnetic field at the external magnetic field supplying unit according to an embodiment of the present invention by using an oscilloscope.

For finding the optimized point of the magnetic field of horizontal and vertical directions by using a characteristic curve of the magneto-resistance sensor, a point of maximizing total magnetic field based on magnetic forces of horizontal and vertical directions is determined. If the magnetic force of horizontal direction is too strong, influence of the magnetic force of vertical direction decreases; otherwise, if the magnetic force of vertical direction is too strong, influence of the magnetic force of horizontal direction decreases. Accordingly, by controlling the magnetic force of horizontal direction, a range of minimizing hysteresis effect can be found; and in the range, a point of maximizing the magnetic field of vertical direction is found in a range of affecting an adverse effect to the magneto-resistance sensor. Herein, the hysteresis effect is a phenomenon that two curves about variations of magnetic flux density occurred by increasing and decreasing magnetic field when an iron is magnetized are not united but respectively form different curves including loop shapes. In the present invention, minimizing the hysteresis effect is to determine a point of minimizing a hysteresis loss, wherein the hysteresis loss is a damage of energy of which amount is corresponding to an area of the loop shapes when AC currents flow into a coil made from the iron.

In the figure, the point ‘P’ is an optimized point of magnetic forces of horizontal and vertical directions. At the point ‘P’, a magnetic force of horizontal direction is 30 Gauss and a magnetic force of vertical direction is 1200 to 1400 Gauss.

Hereinafter, design and structure of the measurement system using the external magnetic field supplying unit according to an embodiment of the present invention.

In the present invention, a target can include a biomaterial such as antigens, and further include a non-biomaterial. The mounting means that the target applies a material such as antigens to a target locking unit fixing the target, being combined with the target locking unit and sensed.

According to embodiments, the magneto-resistance sensor can include various types of sensors having different characteristics. In details, an ordinary magneto-resistance (OMR) sensor using variation of resistance due to trace change of conduction electron because of Lorentz force when an external magnetic field is applied to a non-magnetic conductive material and a semiconductor material has a characteristic of small variation on resistance.

An anisotropic magneto-resistance (AMR) sensor uses an anisotropic magneto-resistance. For example, in a ferromagnetic material including easy axes and hard axes for magnetization by d-band splitting due to spin-orbit coupling, there is a general magneto-resistance as well as the anisotropic magneto-resistance which is determined by both directions of an external magnetic field and a current and a degree between them. This characteristic of the AMR sensor causes resistance difference of about 2.5% according to each direction.

A giant magneto-resistance (GMR) sensor includes a larger several times or more magneto-resistance than the AMR sensor. According to a relative spin direction of an adjacent magnetic layer, variation of resistance is occurred due to additional scattering of conduction electron. Thus, the GMR sensor is basically different from the OMR sensor and the AMR sensor.

A colossal magneto-resistance (CMR) sensor first suggested by von Helmholtz in 1993 has a characteristic of making a resistance multiply every 10 times when a magnetic field is applied.

A tunneling magneto-resistance (TMR) sensor is also available for the magneto-resistance sensor in the present invention. The tunneling magneto-resistance is occurred by a tunneling effect as one of quantum mechanical effect. In TMR sensor, an insulating material is inserted between two ferromagnetic materials. Theoretically, current cannot flow through the insulating material; but if the insulating material is too thin, e.g., a nano film, electrons jump over the insulating material so that current can flow through the insulating material due to the tunneling effect.

A magnetic tunneling junction (MJT) sensor is similar to the TMR sensor. A spin dependent tunneling (SDT) sensor using a spin up/down phenomenon to measure variation of magneto-resistance such as GMR or TMR device is also available for the magneto-resistance sensor in the present invention.

The magneto-resistance sensor in the present invention can be fabricated in a bare chip or a package.

The target locking unit according to an embodiment of the present invention can be formed in a measurement cartridge or a membrane. A magnetic signal of the target may be measured in either contactless method by using a measurement cartridge or a membrane or direct contact method by loading the target on the magneto-resistance sensor.

FIG. 15 is a block diagram showing a measurement system including an additional element for increasing efficiency of sensitivity according to an embodiment of the present invention. The measurement system further comprises an external magnetic field supplying unit shown in FIG. 6.

The measurement system includes a magneto-resistance sensor, a target locking unit, the external magnetic field supplying unit as well as additional element for increasing efficiency of sensitivity. That is, in the embodiment, the measurement system further comprises a scanner configured to scan a magnetic signal sensed by the magneto-resistance sensor. The measurement system further comprises a loader configured to fix the scanner to the target locking unit and a target supporting unit for supporting the target.

The measurement system further comprises a driving unit configured to move back and forth the target supporting unit and the magneto-resistance sensor in response to a predetermined frequency signal and a measurement processing unit configured to extract and analyze electronic component from the magnetic signal sensed by the magneto-resistance sensor.

Referring to figures, the target locking unit such as a measurement cartridge or a membrane is attached to the loader of the scanner; and under (below) or on (above) the magneto-resistance sensor, the scanner scans the target from side to side. Between the target and the magneto-resistance sensor, the external magnetic field supplying unit shown in FIGS. 6 and 7 can be included as above described.

A size of the scanner can be changed according to a size of the external magnetic field supplying unit equipped within the scanner. Operating range of the scanner is in about 10 mm from it center, and operating speed is in range of 0.005 to 5.0 mm/sec or 0.0005 to 50 mm/sec. The scanner can output the result in real time.

The measurement system operates the scanner configured to scan a magnetic signal as following method.

A GMR sensor for biomaterial has a characteristic of sensitivity in inverse proportion to the cube of distance. Accordingly, plural-meters are equipped for obtaining the minimum distance after the loader is installed. Then, the GMR sensor is located to maximize variation of sensitivity in response to a location or distance of the target material.

A measurement cartridge or a membrane fixing a biomaterial such as antigens or a specimen for measurement outputs a stable signal due to back and forth scanning, and post time in the back and forth scanning is in a range of 0 to 10 sec. to minimize a signal offset due to sensing response relaxation.

This measurement method has an advantage to a GMR sensor for biomaterial because the GMR sensor outputs a high signal in a dynamic moment rather than a static condition and to experiment for recognizing a distribution profile of the bio-material in the measurement cartridge or the membrane. As the measurement cartridge or the membrane, point of care testing (POCT) products can be used; but later, a size and a design can be adjusted.

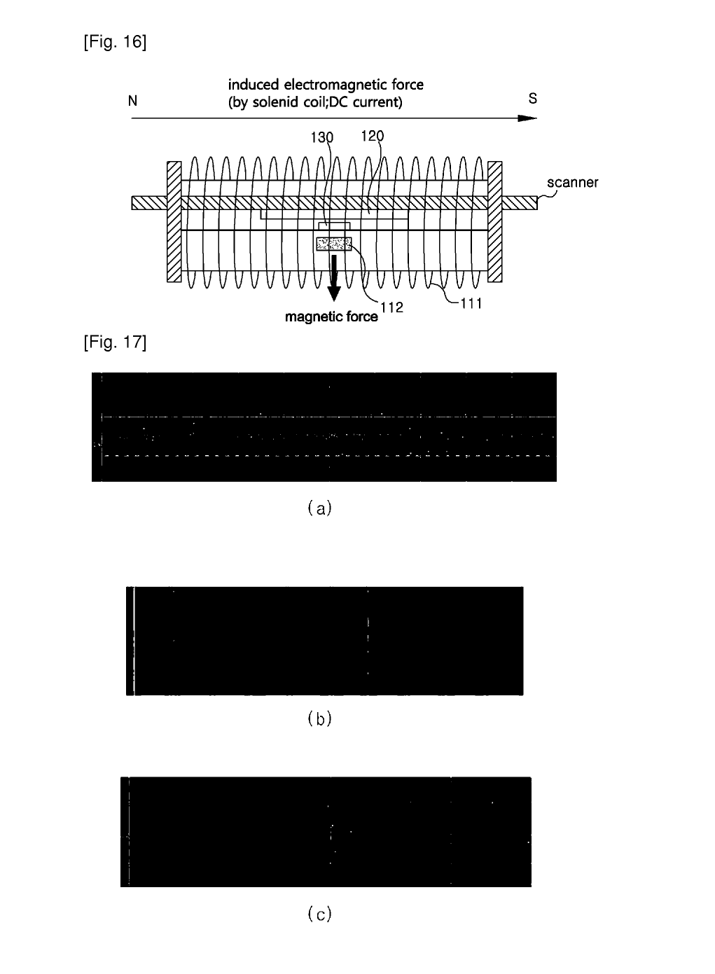

Referring to FIG. 16, the measurement system includes a first supply unit 111 configured to provide a magnetic field of horizontal direction (Y-axis) to the magneto-resistance sensor, a second supply unit 112 configured to provide a magnetic field of vertical direction (Z-axis) to the magneto-resistance sensor, a target material such as a membrane, and a scanner.

As described above, in the measurement system, a DC magnetic field is applied to a side flow membrane in a Z-axis direction to achieve saturation magnetization of magnetic particles having a characteristic of super paramagnetism, and the magnetic field of Y-axis direction is applied to control bias in order to maximize sensitivity of the sensor. That is, measurement target 112 is transferred in Y-axis direction so that sensitivity of the sensor is increased by scanning in Y-axis direction.

In an embodiment of the present invention, a magnetic field provided from the first supply unit 111 including a solenoid coil is controlled in a range of 10 to 150 Gauss, and in the range, the measurement system is designed for maximizing sensitivity. Herein, the uniformity of provided magnetic field can be controlled less than 1%. Characteristics of the solenoid coil, e.g., a diameter of cylinder, a diameter of coil, and the coiled-up number, are designed for optimized condition, but according to an embodiment, characteristics of the solenoid coil may be changed.

Herein, an external magnetic field supplying unit includes a solenoid coil as well as a Helmholtz coil, an electromagnet yoke, a permanent magnet, and so on. That is, according to an embodiment, the external magnetic field supplying unit includes one or more of a solenoid coil, a Helmholtz coil, an electromagnet yoke, a permanent magnet, and etc., and the first and second supply units can includes the same or different components.

The Helmholtz coil used as the first supply unit 111 in the external magnetic field provides a magnetic field of horizontal direction (Y-axis) to the GMR sensor. The magnetic field of Y-axis direction allows the GMR sensor to always sense under stable or the same condition, and helps the GMR sensor to set a preferable range of sensitivity and reliability within an operation range.

The permanent magnet used as the second supply unit 112 provides a magnetic field of vertical direction (Z-axis) to the GMR sensor. The magnetic field of Z-axis can be controlled in a range of 1000 to 4500 Gauss. There is no limitation to size and shape of the permanent magnet. Since the magnetic field of vertical direction does not affect to the GMR sensor, a strength of the magnetic field of vertical direction occurred by the permanent magnet is not limited.

The magnetic field of vertical direction occurred by the permanent magnet may affect localized accumulation of magnetic particles in a membrane. Due to the magnetic field, the magnetic particles has a magnetizing force, and a strength of a magnetic force occurred from the magnetic particles is in proposition to a strength of the magnetic field occurred by the permanent magnet.

The external magnetic field generated by the Helmholtz coil and the permanent magnet increases sensitivity of the GMR sensor. The magnetic field generated by the permanent magnet vertical to the GMR sensor has no effect to sensitivity of the GMR sensor, but strongly magnetize the magnetic particles in the membrane to increase sensitivity of the GMR sensor.

FIG. 17 shows measurement results on an experiment using a measurement system according to an embodiment of the present invention. In the experiment, magnetic materials of 30 to 50 emu/g are included in the membrane. An external magnetic field provided from the Helmholtz coil is 30 Gauss, a distance between the GMR sensor and the membrane is about 100 to 250 m, and a scanning speed is about 24 mm/sec. These conditions are changeable, not fixed.

The permanent magnet configured to magnetize magnetic particles accumulated in the membrane has a rectangular shape of 20 mm length and breadth and 10 mm thickness. At surface of the permanent magnet, magnetic force is about 4500 Gauss; and at a predetermined distance from the permanent magnet, magnetic force is in range of 1000 to 2000 Gauss. Herein, size, shape, and strength of magnetic field of the permanent magnet can be changeable.

In FIG. 17, Case (a) is that measurement to localized accumulation of magnetic particles is 520 mV and a signal-to-noise ratio is 4 if a magnetic field of horizontal direction (Y-axis) is only occurred; case (b) is that the measurement is 4340 mV and the signal-to-noise ratio is 33 if a magnetic field of horizontal and vertical directions; and case (c) is that the measurement is 5080 mV and the signal-to-noise ratio is 39 if a magnetic field of horizontal and vertical directions and a biasing is controlled. This result says that sensitivity of the sensor is increased when the magnetic field of both horizontal and vertical directions is applied.

Hereinafter, design and structure of the measurement system using the external magnetic field supplying unit according to an embodiment of the present invention. In the present invention, a target can include a biomaterial such as antigens, and further include a non-biomaterial. The mounting means that the target applies a material such as antigens to a target locking unit fixing the target, being combined with the target locking unit and sensed.

According to an embodiment of the present invention, a system for measuring target particles using a magneto-resistance sensor is provided, wherein a measurement system may maximizes sensitivity of the magneto-resistance sensor by supplying a magnetic field in directions of Y and Z axes of the magneto-resistance sensor. Further, to maximize sensitivity, the measurement system includes a magnetic compensating unit for forming a magnetic field of Z-axis direction by circulating the magnetic field being loss to keep strength of magnetic field and efficiency of high sensitivity.

In details, to maximize sensitivity of the magneto-resistance sensor, the measurement system applies both a DC magnetic field is applied to a side flow membrane in a Z-axis direction to achieve saturation magnetization of magnetic particles having a characteristic of super paramagnetism and the magnetic field of Y-axis direction in order to maximize sensitivity of the sensor.

According to an embodiment, the measurement system mounts the target to the target locking unit, applies an external magnetic field in two directions to the magneto-resistance sensor by using the external magnetic field supplying unit, and senses a magnetic signal of the target connected to magnetic particles by using the magneto-resistance sensor to extract and analysis an electric component.

An external magnetic field is provided by using two supply units including one or more of a solenoid coil, a Helmholtz coil, an electromagnet yoke, a permanent magnet, and etc.; and at this time, magnetization of the magnetic particles is maximized and effects to the magneto-resistance sensor is minimized so that efficiency of sensitivity is maximized.

The present invention can couple a giant magneto resistance cartridge as a cartridge for biomaterial measurement to a measurement processing unit so that an electro component can be extracted and analyzed after the target combined with magnetic particles are detected and sensed. Further, if a GMR device fabricated by a conventional art is applied as a bio sensor, sensitivity to small target can be increased by contactless way between a sensing element and the target so that quantitative analysis can be smoothly performed.

Furthermore, the present invention allows Bio-diagnostics by using a contactless GMR sensor to sense a target or a specimen. If a membrane used in point of care testing (POCT) is installed to a measurement kit, more effective measurement system for the membrane can be developed.

In addition, the present invention may overcome a sensing range restricted by a size of sensing element and perform a quantitative analysis for measurement because a noise among frequencies can be classified by a dynamic scanning method.

It will be apparent to those skilled in the art that various modifications and variation can be made in the present invention without departing from the spirit or scope of the invention. Thus, it is intended that the present invention cover the modifications and variations of this invention, provided they come within the scope of the appended claims and their equivalents.

1. A measurement system using a magneto-resistance sensor, comprising:
a magneto-resistance sensor configured to sense a magnetic component of a target combined with a magnetic particles; and
an external magnetic field supplying unit configured to provide an external magnetic field of a first and a second directions to the magneto-resistance sensor,
wherein the external magnetic field supplying unit comprises a magnetic field compensating unit configured to compensate a loss of magnetic field by circulating the external magnetic field of the second direction.

2. The measurement system according to claim 1, wherein the magnetic field compensating unit comprises:
a magnetic field circulating module configured to circulate an outflow portion of the external magnetic field; and
a magnetic field generating unit included inside the magnetic field circulating module.

3. The measurement system according to claim 2, wherein the magnetic field circulating module comprises magnetic field generating units arranged in opposite sides in an interior space and a closed structure for circulating a magnetic field at an outer space.

4. The measurement system according to claim 1, wherein the external magnetic field supplying unit comprises:
a first supply unit configured to provide a magnetic field of horizontal direction (Y-axis) to the magneto-resistance sensor; and
a second supply unit configured to provide a magnetic field of vertical direction (Z-axis) to the magneto-resistance sensor.

5. The measurement system according to claim 4, wherein the first and second supply units are formed in one body.

6. The measurement system according to claim 4, wherein magnetic field generating units of the first and second supply units includes one or more of a solenoid coil, a Helmholtz coil, an electromagnet yoke, and a permanent magnet.

7. The measurement system according to claim 2, wherein the magneto-resistance sensor includes a giant magneto-resistance (GMR) sensor.

8. The measurement system according to claim 2, wherein a magnetic field generated by the first supply unit is formed in response to a DC current.

9. The measurement system according to claim 2, wherein a range of magnetic field of the first supply unit or a response available range of the magneto-resistance sensor is 200 to 300 Gauss.

10. The measurement system according to claim 9, wherein a range of magnetic field of the second supply unit is 1000 to 4500 Gauss.

11. The measurement system according to claim 2, further comprising a target locking unit configured to fix the target, wherein the target locking unit includes a measurement cartridge or a membrane.

12. The measurement system according to claim 2, wherein the target comprises a biomaterial including antigens.

13. The measurement system according to claim 2, wherein the magnetic component is sensed contactless a measurement cartridge or a membrane.

14. The measurement system according to claim 2, further comprising a scanner configured to scan the magnetic component sensed by the magneto-resistance sensor.

15. The measurement system according to claim 14, wherein the scanner comprises:
a target supporting unit configured to support the target; and
a loader configured to load the target locking unit fixing the target.

16. The measurement system according to claim 15, further comprising a measurement processing unit configured to extract and analyze electronic component from a magnetic signal sensed by the magneto-resistance sensor to output an analysis result.

17. The measurement system according to claim 2, wherein the magnetic particles have a magnetizing force of 10 to 100 emu/g.

18. The measurement system according to claim 17, wherein the magnetic particles have a characteristic of super paramagnetism or paramagnetism.

19. The measurement system according to claim 9, wherein a range of magnetic field of the second supply unit is 1200 to 1400 Gauss.

20. A method for performing a quantitative measurement to a target by applying an external magnetic field to a magnetic particles and using a magneto-resistance sensor, comprising:
providing a DC magmatic field for magnetizing the magnetic particles in a vertical direction (Z-axis) to the magneto-resistance sensor;
providing an induced magnetic field in a horizontal direction (Y-axis) to the magneto-resistance sensor into the target to perform a measurement;
choosing a value corresponding to point of minimizing a hysteresis range on a characteristic curve of the magneto-resistance sensor as a horizontal value;
choosing a maximized value in a range of fixed characteristic of the magneto-resistance sensor as a vertical value; and
determining an optimized point of the horizontal and vertical values as a measurement.

21. A measurement system using a magneto-resistance sensor, comprising:
a magneto-resistance sensor configured to sense a magnetic component of a target combined with a magnetic particles; and
an external magnetic field supplying unit configured to provide an external magnetic field of a first and a second directions to the magneto-resistance sensor.

22. The measurement system according to claim 21, wherein a range of magnetic field of a second supply unit included in the external magnetic field supplying unit is 1000 to 4500 Gauss.

23. The measurement system according to claim 21, wherein a range of magnetic field of a second supply unit included in the external magnetic field supplying unit is 1200 to 1400 Gauss.

24. A method for performing a quantitative measurement to a target by applying an external magnetic field to a magnetic particles and using a magneto-resistance sensor, comprising:
providing a DC magmatic field for magnetizing the magnetic particles in a vertical direction (Z-axis) to the magneto-resistance sensor; and
providing an induced magnetic field in a horizontal direction (Y-axis) to the magneto-resistance sensor into the target to perform a measurement.
